(19) United States
(12) Patent Application Publication
(10) Pub. No.: US 2021/0040608 A1
(43) Pub. Date: Feb. 11, 2021

(54) METHOD FOR BONDING A POLYMERIC MATERIAL TO A SUBSTRATE

(71) Applicant: GM GLOBAL TECHNOLOGY OPERATIONS LLC, Detroit, MI (US)

(72) Inventors: Anthony M. Coppola, Rochester Hills, MI (US); Gayatri V. Dadheech, Bloomfield Hills, MI (US); Alireza Fatemi, Canton, MI (US)

(73) Assignee: GM GLOBAL TECHNOLOGY OPERATIONS LLC, Detroit, MI (US)

(21) Appl. No.: 16/531,638

(22) Filed: Aug. 5, 2019

(51) Int. Cl. C23C 16/40; C23C 16/511; C23C 16/02; C23C 16/56; B05D 3/14; B05D 7/00

(52) U.S. Cl. CPC C23C 16/402; C23C 16/511; C23C 16/02; C23C 16/56; B05D 2202/15; B05D 7/52; B05D 2350/60; B05D 2201/02; B05D 3/142

(57) ABSTRACT

A method for bonding a polymeric fill material onto a surface of a substrate is described, and includes exposing the surface of the substrate to a microwave-generated argon-hydrogen plasma for a predetermined time period, applying, via a microwave plasma chemical vapor deposition process, a SiOx surface coating onto the surface of the substrate, and executing a post-treatment process to the SiOx surface coating. The polymeric fill material may be applied onto the substrate and subjected to curing.

### INTRODUCTION

Devices such as rotary electric machines, e.g., motor-generator units, include a rotor configured to rotate about a shaft defining an axis, and a stator. During rotation, the rotor experiences mechanical stresses as the electro-magnetic force generated via the stator is converted to torque that is transferred to the rotor shaft. The dynamic speed and torque operating range of the electric machine may be limited based upon the mechanical stresses.

High speed rotors for electric machines may have cavities or void areas that may be filled with a fill material, which may facilitate increased torque, speed, and durability of the electric machine. However, stress transfer between the materials will not occur if there is no bond. Mechanical interlocks improve load transfer, but a chemical bond between the materials may further enhance bonding.

Industrially known adhesion promoting processes like open air plasma may have limited success because they require a line-of-sight in order to accomplish the task. However, rotors having a complex three-dimensional geometry may include portions that have no line of sight for plasma jet cleaning. Furthermore, open air plasma removes only surface contaminants.

### SUMMARY

As described herein, a method for bonding a polymeric fill material to a surface of a substrate includes microwave plasma chemical vapor deposition of a thin (<50 nm) surface coating of silicon-oxide (SiOx) material to promote chemical bonding for strong adhesion. The SiOx coating may be produced by using any derivative of siloxane, silanols or silane based precursor chemistry. The coating process includes a preclean step, a SiOx deposition step, and a post-deposition step to attach polar groups. The resultant coating is shelf stable, meaning there is no specific timing required between applying the coating and applying the polymeric fill material.

The method for bonding a polymeric fill material onto a surface of a substrate includes exposing the surface of the substrate to a microwave-generated argon-hydrogen plasma for a predetermined time period, applying, via a microwave plasma chemical vapor deposition process, a SiOx surface coating onto the surface of the substrate, and executing a post-treatment process to the SiOx surface coating. The polymeric fill material may be applied onto the substrate and subjected to curing.

An aspect of the disclosure includes exposing the surface of the substrate to the microwave-generated argon-hydrogen plasma at 600 W of power for at least sixty seconds.

Another aspect of the disclosure includes applying, via the microwave plasma chemical vapor deposition process, the SiOx surface coating onto the surface of the substrate by feeding a precursor containing a silicon-oxide material with a carrier gas onto the surface of the substrate employing the microwave plasma chemical vapor deposition process.

Another aspect of the disclosure includes the precursor containing the silicon-oxide material with the carrier gas being hexamethyldisiloxane (HMDSO) as the precursor and oxygen (O₂) as the carrier gas.

Another aspect of the disclosure includes the precursor containing the silicon-oxide material with the carrier gas being triethoxy silane as the precursor and oxygen (O₂) as the carrier gas.

Another aspect of the disclosure includes feeding the precursor containing the silicon-oxide material with the carrier gas at a ratio of 10% of the precursor to the carrier gas.

Another aspect of the disclosure includes applying the surface coating onto the surface of the substrate employing the microwave plasma chemical vapor deposition process by operating at a microwave power of 100 W at a frequency of 2.45 GHz at a temperature of 45 C.

Another aspect of the disclosure includes executing the post-treatment process to the surface coating by exposing the surface coating to a gas composed of at least one of oxygen and nitrogen gases.

Another aspect of the disclosure includes the surface of the substrate being fabricated from electrical steel.

Another aspect of the disclosure includes the surface of the substrate being fabricated from a metal-based substrate.

Another aspect of the disclosure includes the metal-based substrate being a substrate fabricated from one of stainless steel, aluminum, electrical steel, low carbon steel, and magnesium.

Another aspect of the disclosure includes the surface of the substrate being fabricated from a plastic-based substrate.

Another aspect of the disclosure includes the plastic-based substrate being a substrate fabricated from one of a polyurethane, a polycarbonate, a polyethylene, and a polytetrafluoroethylene (PTFE).

Another aspect of the disclosure includes the polymeric filler material adhering to the surface of the substrate via the surface coating subsequent to the curing.

Another aspect of the disclosure includes inserting a permanent magnet into the substrate, and then exposing the surface of the substrate and a surface of the permanent magnet to a microwave-generated argon-hydrogen plasma for the predetermined time period and applying, via the microwave plasma chemical vapor deposition process, the SiOx surface coating onto the surface of the substrate and the surface of the permanent magnet.

Another aspect of the disclosure includes the polymeric filler material adhering to the surface of the substrate and the permanent magnet via the surface coating subsequent to the curing.

Another aspect of the disclosure includes a method for bonding a polymeric fill material onto a surface of a substrate by exposing the surface of the substrate to a microwave-generated argon-hydrogen plasma for a predetermined time period, applying, via a microwave plasma chemical vapor deposition process, an adhesive-enhancing surface coating onto the surface of the substrate, executing a post-treatment process to the surface coating, executing a silane-coupling process to the surface coating, applying the polymeric fill material onto the substrate.

Another aspect of the disclosure includes applying, via the microwave plasma chemical vapor deposition process, the adhesive-enhancing surface coating onto the surface of the substrate by feeding a precursor containing a silicon-oxide material with a carrier gas onto the surface of the substrate employing the microwave plasma chemical vapor deposition process.

Another aspect of the disclosure includes a method for preparing a surface of a substrate, including exposing the surface of the substrate to a microwave-generated argon-hydrogen plasma for a predetermined time period, applying, via a microwave plasma chemical vapor deposition process, a SiOx surface coating onto the surface of the substrate, and executing a post-treatment process to the surface coating.

Another aspect of the disclosure includes applying, via the microwave plasma chemical vapor deposition process, the SiOx surface coating onto the surface of the substrate by feeding a precursor containing a silicon-oxide material with a carrier gas onto the surface of the substrate employing the microwave plasma chemical vapor deposition process.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

One or more embodiments will now be described, by way of example, with reference to the accompanying drawings, in which:

FIG. 1 schematically shows an isometric cutaway view of an electric machine, in accordance with the disclosure;

FIG. 2 schematically shows an end-view of a lamination for a rotor, in accordance with the disclosure.

FIG. 3A schematically shows an isometric partially exploded view of an embodiment of a rotor for an electric machine, in accordance with the disclosure.

FIG. 3B schematically shows an isometric partially exploded view of another embodiment of a rotor for an electric machine, in accordance with the disclosure.

FIG. 4 schematically shows a partial end view of a lamination for a rotor, in accordance with the disclosure.

FIG. 5 schematically shows an embodiment of a process for assembling an embodiment of a rotor, in accordance with the disclosure.

FIG. 6 schematically shows another embodiment of a process for assembling an embodiment of a rotor, in accordance with the disclosure.

FIG. 7 schematically shows an embodiment of a process for applying the adhesive-enhancing surface coating to a substrate, in accordance with the disclosure.

FIG. 8 illustrates a reaction mechanism associated with bonding a fill material onto a surface of a substrate, in accordance with the disclosure.

The appended drawings are not necessarily to scale, and may present a somewhat simplified representation of various preferred features of the present disclosure as disclosed herein, including, for example, specific dimensions, orientations, locations, and shapes. Details associated with such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments can be practiced without some of these details. Moreover, for the purpose of clarity, certain technical material that is understood in the related art has not been described in detail in order to avoid unnecessarily obscuring the disclosure. Furthermore, the drawings are in simplified form and are not to precise scale. For purposes of convenience and clarity, directional terms such as top, bottom, left, right, up, over, above, below, beneath, rear, and front, may be used with respect to the drawings. These and similar directional terms are not to be construed to limit the scope of the disclosure. Furthermore, the disclosure, as illustrated and described herein, may be practiced in the absence of an element that is not specifically disclosed herein.

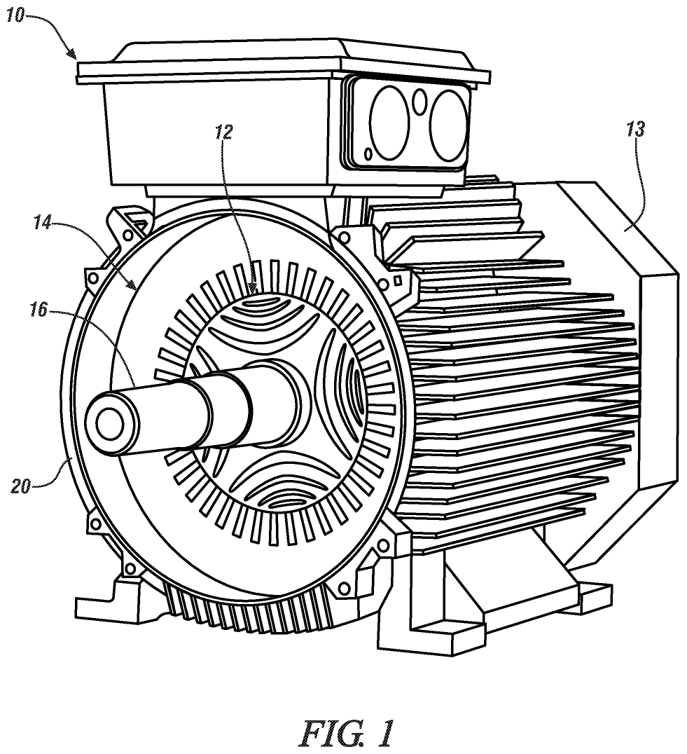

Referring to the drawings, wherein like reference numerals correspond to like or similar components throughout the several Figures, FIG. 1, consistent with embodiments disclosed herein, illustrates an electric machine 10. In one embodiment, the electric machine 10 may be arranged to generate tractive power for a vehicle. The vehicle may include, but not be limited to a mobile platform in the form of a commercial vehicle, industrial vehicle, agricultural vehicle, passenger vehicle, aircraft, watercraft, train, all-terrain vehicle, personal movement apparatus, robot and the like to accomplish the purposes of this disclosure. The electric machine 10 may be configured as an electric motor that is capable of transforming electric power to mechanical torque, a generator that is capable of transforming mechanical torque to electric power, or as a motor/generator that is capable of both.

The electric machine 10 includes a housing 20 and opposed end caps 13, one of which is shown. The housing 20 includes an annular opening into which a stator 14 is inserted. The stator 14 includes an annular opening into which a rotor 12 is inserted. The rotor 12 is mounted on a shaft 16, and the shaft 16 is supported on bearings mounted in the end caps 13. One end of the shaft 16 projects axially out of one of the end caps 13 and couples to a gear, pulley, or other device for torque transfer.

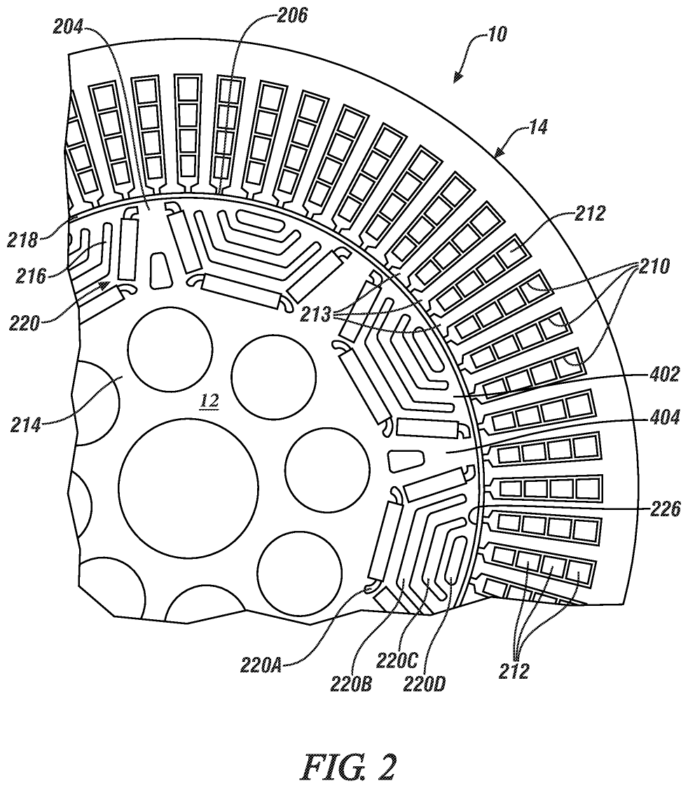

Referring now to FIG. 2, a cutaway end-view of a portion of an embodiment of the electric machine 10, including rotor 12 and stator 14 is schematically shown. The stator 14 may be, for example, a multi-phase stator assembly. The stator 14 is coaxial with and radially surrounds the rotor 12 while maintaining a space 206 therebetween. In some embodiments, the space 206 is between about 0.2 millimeters (mm) and about 1.0 mm to thereby maximize power output while reducing likelihood of contact between the stator 14 and the rotor 12 during rotation thereof. The stator 14 is generally annular along a longitudinal axis of the rotor 12. In one embodiment, a protective motor body (not shown) may surround an outer periphery of the stator 14 and may support the motor-generator shaft 208.

The stator 14 may include multiple radially elongated, circumferentially spaced stator slots 210 (e.g., 60 total slots). The stator slots 210 extend through the stator 14 longitudinally along the longitudinal axis. The stator slots 210 are configured to house electrically conductive, multiphase stator windings 212. The stator windings 212 may be grouped into different sets, each of which may carry an identical number of phases of electrical current, such as three, five, six, or seven phases. Passing current through the stator windings 212 will generate a magnetic field at the stator teeth 213. In addition, the stator windings 212 may extend axially beyond the longitudinal ends of the stator 14. A ratio of an outer diameter of the stator 14 to an axial length of the stator 14 (e.g., the distance along the axis A between the body's longitudinal ends not including an extending portion of the stator windings 212) may be, by way of non-limiting example, not less than 1.5:1 and not greater than 3.5:1. The ratio may be determined at least to satisfy packing space constraints for a particular application of the electric machine 10.

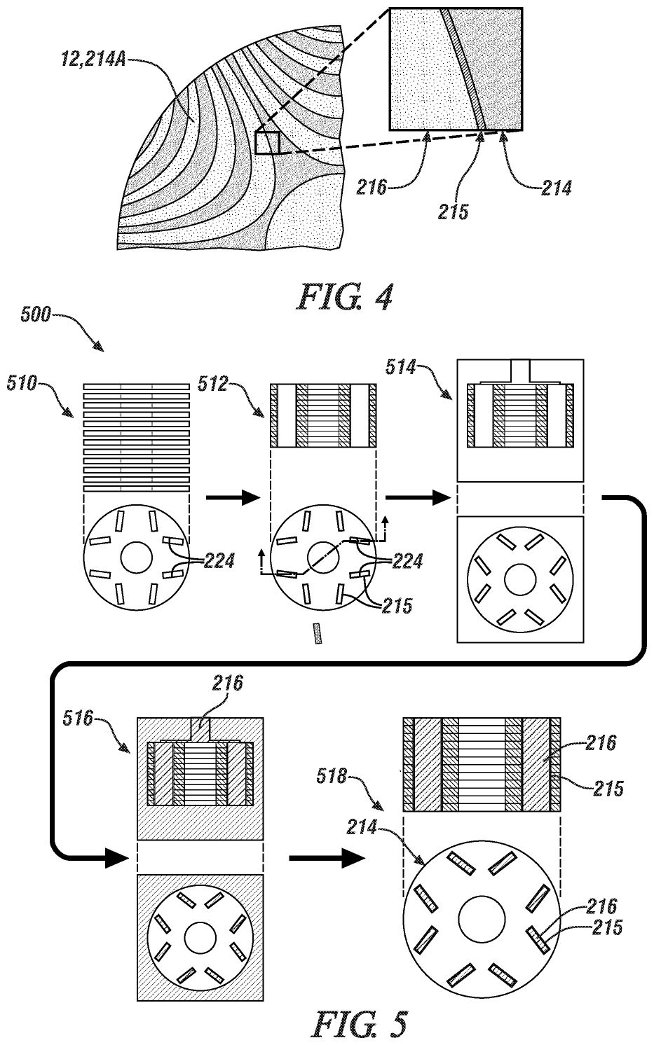

The rotor 12 is disposed about the motor-generator shaft 208 and may be splined, attached, fused, or otherwise rotationally fixed thereto. The rotor 12 is arranged as a laminated structure, and generally defines a right circular cylinder. The rotor 12 includes a plurality of ferromagnetic components 214 in the form of disc-shaped laminations, an adhesive-enhancing surface coating 215 and a polymeric fill material 216, as illustrated with reference to FIG. 4.

As can be seen, the ferromagnetic components 214, in combination with the polymeric fill material 216, are configured to produce a substantially continuous circular peripheral edge 218 of the rotor 12. The ferromagnetic components 214 may be arranged such that the rotor 12 includes a plurality of flux barriers 220 circumferentially arranged about the motor-generator shaft 208 between the motor-generator shaft 208 and the peripheral edge 218 of the rotor 12.

The flux barriers 220 have different magnetic properties from at least one adjacent component. For example, the flux barriers 220 may be non-magnetic while the adjacent portions are ferromagnetic. In some embodiments, the flux barriers 220 are provided in the form of a generally non-magnetic material disposed between ferromagnetic components 214. In some embodiments, the flux barriers 220 or selections thereof include one or more permanent magnets disposed therein. For example, the innermost, first through third layers 220A-220C include or are filled with permanent magnets while the outermost, fourth layer 220D does not include permanent magnets in one embodiment when the electric machine 10 is configured as an interior permanent magnet device. In further examples, the permanent magnets may be disposed in alternating layers, such as the first layer 220A and the third layer 220C, while the remaining layers do not include permanent magnets.

The ferromagnetic components 214 are formed from a ferromagnetic material configured to provide desired magnetic characteristics. For example, the ferromagnetic material may be electrical steel, iron, nickel, cobalt, combinations thereof, or the like. The laminated structure may be formed by, for example, stacking a plurality of ferromagnetic components 214 along the axis of rotation.

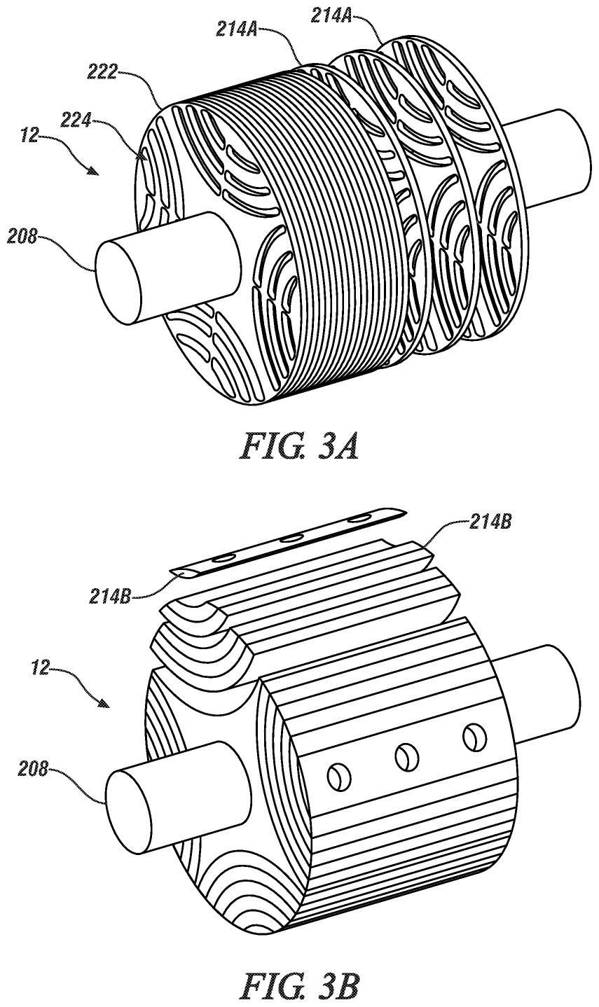

In one embodiment, the plurality of ferromagnetic components 214 may be configured as a plurality of disc-shaped laminations 214A, such as those illustrated in FIG. 3A, and the laminated structure is formed by the plurality of disc-shaped laminations 214A being stacked axially along the motor-generator shaft 208 such that each of the disc-shaped laminations 214A extends radially therefrom. The disc-shaped laminations 214A may be produced by forming, machining, molding, additive manufacturing processes, combinations thereof, and the like. For example, milling, stamping, extruding, metal injection molding, cutting, combinations thereof, and the like may be employed to produce plates having a desired shape or desired shapes.

The plurality of ferromagnetic components 214 may be configured as plurality of members 214B, such as those illustrated in FIG. 3B, and the laminated structure is formed by the plurality of members 214B being arranged radially around the motor-generator shaft 208 and extending at least partially longitudinally therealong. The members 214B may be correspondingly shaped such that assembly of the plurality of members 214B results in the right circular cylinder. The members 214B may be produced by forming, machining, molding, additive manufacturing processes, combinations thereof, and the like. For example, milling, stamping, extruding, metal injection molding, cutting, combinations thereof, and the like may be employed to produce members having a desired shape or desired shapes. In some embodiments, the plurality of ferromagnetic components 214 is configured to provide the rotor 12 with a saliency ratio of about 2 to about 10.

The adhesive-enhancing surface coating 215 is composed as a silicon-oxide (SiOx) material, which may be applied to surfaces of the ferromagnetic components 214 to promote and enhance adhesive bonding between the ferromagnetic components 214 and the polymeric fill material 216. The surface coating 215 can be produced using any derivative of siloxane, silanols or silane-based precursor chemistry. In one embodiment, the surface coating 215 is applied to the surfaces of the ferromagnetic components 214 at a thin layer thickness, e.g., less than 50 nm. In one embodiment, the surface coating 215 is applied to the surfaces of the ferromagnetic components 214 at a layer thickness that is on the order of magnitude of 20 nm.

The polymeric fill material 216 may be an adhesive material providing high flexural strength, minimal void content, and full contact area. The polymeric fill material 216 may be an epoxy, a phenol, a silicone, or a polyurethane. In one embodiment, the polymeric fill material 216 has magnetic properties selected to strengthen the magnetic field of the rotor 12.

The polymeric fill material 216 is configured to transition from a flowable state to a substantially rigid state in response to a curing process. The polymeric fill material 216 occupies the rotor cavities 224 between the ferromagnetic components 214 to maintain positions of the ferromagnetic components 214 during rotation of the rotor 12. In one embodiment, the polymeric fill material 216 occupies all rotor cavities 224. Alternatively, only a portion of the rotor cavities 224 are occupied by the polymeric fill material 216.

The polymeric fill material 216 may be applied to the rotor 12 using, for example, molding techniques such as injection molding or epoxy molding. In some embodiments, the polymeric fill material 216 forms an adhesive bond with edges 222 of the rotor cavities 224 to thereby optimize tensile stresses experienced by the ferromagnetic components 214.

Additionally or alternatively, the edges 222 of the rotor cavities 224 may define profiles to provide a mechanical interlock between the polymeric fill material 216 and the ferromagnetic components 214. For example, the edges 222 may include profiles having alternating protruding and recessed portions, such as a saw-tooth profile, crenellated profile, or cleated profile, such that surface-to-surface sliding between respective portions of the ferromagnetic components 214 and the polymeric fill material 216 is inhibited. In further examples, the edges 222 may include profiles having undercut portions, such as dovetail profiles or circular undercuts, such that both surface-to-surface sliding and delamination are inhibited. Beneficially, profiled edges 222 may be formed simultaneously with formation of the ferromagnetic components.

The profile features may be selected to provide desired mechanical properties. For example, the profiles may be rounded to further inhibit stress concentration present in corners of the material. Further, measure of the undercut angles may be minimized to provide lock-in while optimizing neck size and strength. It is contemplated that combinations of profiles may be provided. For example, edges 222 nearer the motor-generator shaft 208 may have a first profile to accommodate stresses experienced nearer the axis of rotation while edges 222 nearer the periphery of the rotor 12 may have a second profile to accommodate stresses experienced nearer the periphery of the rotor 12, such as those resulting from increased linear velocity and magnetic interactions with the stator 14.

The thermal expansion properties of the polymeric fill material 216 within the rotor cavities 224 are selected to approximate thermal expansion properties of the ferromagnetic components 214. In some embodiments, the effective coefficient of thermal expansion of the polymeric fill material 216 is approximately equal to the coefficient of thermal expansion of the ferromagnetic components 214. In some embodiments, the rotor cavities 224 and/or ferromagnetic components 214 are selectively shaped to mitigate differences in coefficients of thermal expansion for the respective materials.

Because the polymeric fill material 216 provides structural support for the ferromagnetic components 214 during rotation of the rotor 12, flux-leaking components such as the ferrous bridges 402 and the central posts 404 may be reduced in size to mitigate their effects on magnetic flux and flux leakage. Beneficially, in some embodiments, the ferrous bridges 402 and/or central posts 404 are sacrificial components that may be removed after the polymeric fill material 216 is cured. In some embodiments, the sacrificial components are removed via a mechanical process such as milling. In some embodiments, the sacrificial components are a fusible material removed via, for example, chemical or thermal processes. Removal of the sacrificial components, e.g., some of the ferrous bridges 402 and/or central posts 404, facilitates increase in torque output of the electric machine 10.

In some embodiments, the rotor 12 includes an overwrap 226 circumscribing the periphery of the rotor. The overwrap 226 may be, for example, carbon fiber or other composite wraps. Beneficially, the overwrap 226 may be configured to mitigate differences in thermal expansion between the ferromagnetic components 214 and the polymeric fill material 216.

Rotor bodies 204 according to embodiments of the present disclosure provide a number of benefits. For example, rotor bodies as disclosed herein optimize performance of the motor-generator though, for example, (1) strengthened magnetic interactions between the ferromagnetic components of the rotor and electromagnetic components of the stator by reducing space between a periphery of rotor and inner surface of the stator, (2) reducing thickness of or eliminating non-magnetic components disposed between magnetic components of the rotor and magnetic components of the stator, such as sleeves or wraps, and/or (3) reducing thickness of or eliminating flux-leaking components of the rotor disposed proximate the stator. Further, rotor bodies 204 in accordance with the present disclosure provide for an increased number of flux barriers 220 within the same space while maintaining or increasing structural integrity of the rotor 12. Moreover, the polymeric fill material 216 provides structural integrity to the rotor 12 and thereby maintaining structural integrity of the rotor 12 at high RPM, which facilitates improvements in energy efficiency and peak rotational speeds. Beneficially, rotor bodies 204 in accordance with the present disclosure further optimize structural integrity during revolution of the rotor 12 by reducing rotor weight.

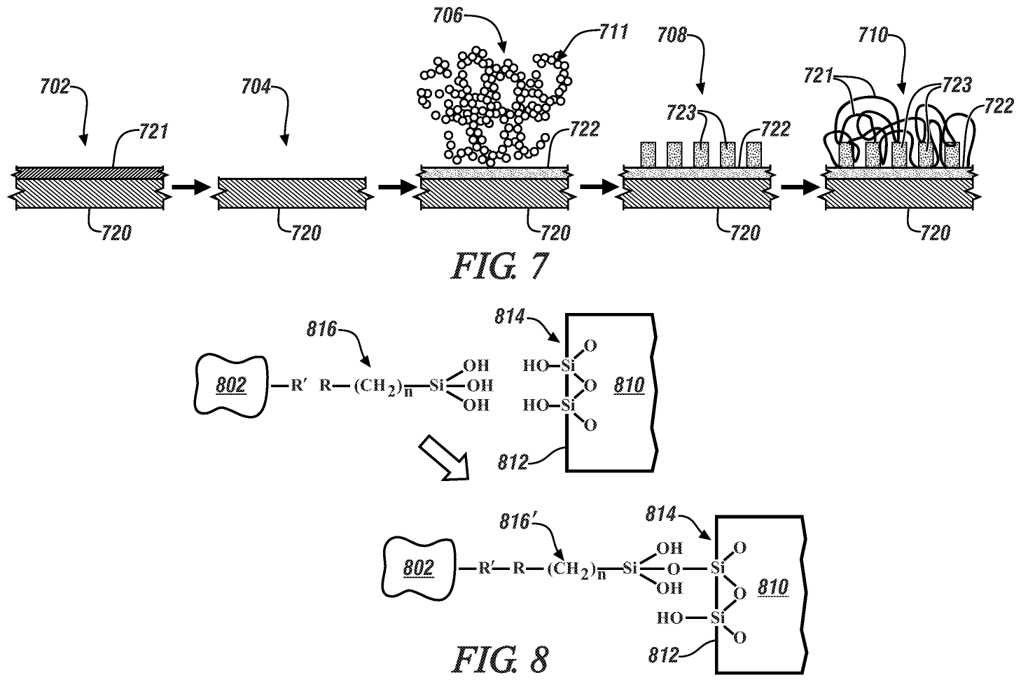

FIG. 5 pictorially shows a process for assembling an embodiment of the rotor 12 described herein, including a side-view and corresponding end-view of the rotor 12 and disc-shaped laminations 214A that are described with reference to FIGS. 2, 3A and 4, including cavities 224. At step 510, a plurality of the disc-shaped laminations 214A are arranged in a stack, and aligned to form a plurality of the cavities 224. At step 512, the adhesive-enhancing surface coating 215 is applied to the cavities 224. Details associated with step 512 to apply the adhesive-enhancing surface coating 215 to the cavities 224 are described with reference to FIG. 7. At step 514, the stack of the disc-shaped laminations 214A is inserted into a mold, and at step 516, the polymeric fill material 216 is added to the mold employing molding techniques such as injection molding or epoxy molding, and cured. At step 518, the assembled rotor 12 is removed from the mold and is ready for additional assembly processes.

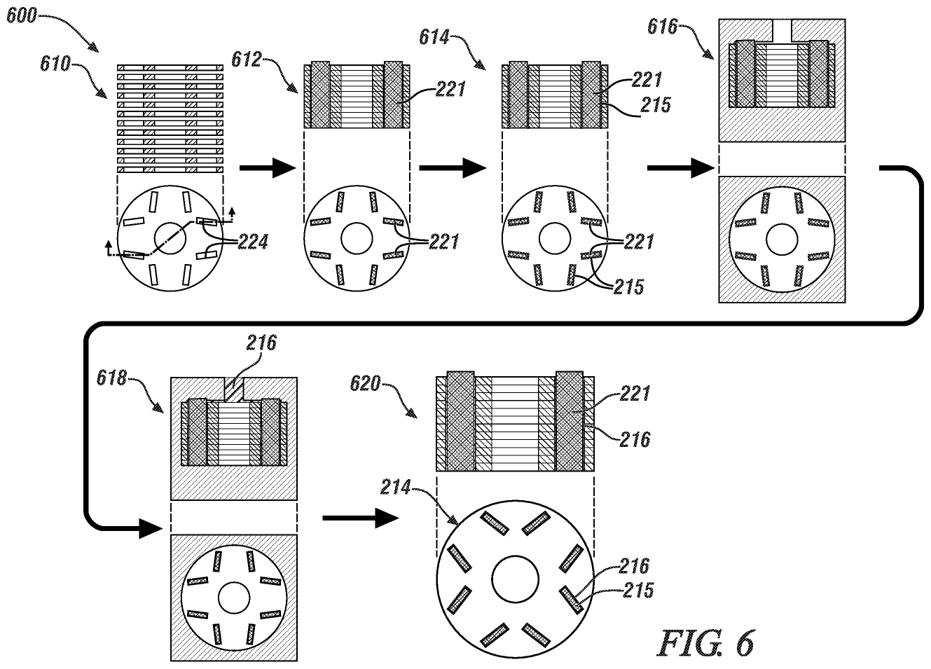

FIG. 6 pictorially shows a process for assembling an embodiment of the rotor 12 described herein, including a side-view and corresponding end-view of the rotor 12 and disc-shaped laminations 214A that are described with reference to FIGS. 2, 3A and 4, including cavities 224. At step 610, a plurality of the disc-shaped laminations 214A are arranged in a stack, and aligned to form a plurality of the cavities 224. At step 612, permanent magnets 221 are inserted into at least a portion of the plurality of the cavities 224. At step 614, the adhesive-enhancing surface coating 215 is applied to the cavities 224 and the permanent magnets 221. Details associated with step 614 to apply the adhesive-enhancing surface coating 215 to the cavities 224 are described with reference to FIG. 7. At step 616, the stack of the disc-shaped laminations 214A is inserted into a mold, and at step 618, the polymeric fill material 216 is added to the mold employing molding techniques such as injection molding or epoxy molding, and is then cured. At step 620, the assembled rotor 12 including the permanent magnets 221 is removed from the mold and is ready for additional assembly processes.

FIG. 7 schematically shows an embodiment of a process 700 for applying an embodiment of the adhesive-enhancing surface coating described herein to a substrate 720. In one embodiment, the substrate may be the cavities 224 of the rotor 12 shown with reference to FIG. 5, or the cavities 224 of the rotor 12 and the permanent magnets 221 shown with reference to FIG. 6. The process 700 includes an initial step 702, a pretreatment step 704, a surface coating step 706, a post-treatment step 708, and a coupling step 710.

The initial step 702 includes positioning the substrate 720 including organic contaminants 721 in the device for processing.

The pretreatment step 704 includes exposing the surface of the substrate 720 to a microwave-generated argon-hydrogen plasma for a predetermined time period. The pretreatment step 704 cleans and removes the organic contaminants 721 from the substrate 720 that may be residing as a result of manufacturing processes, part handling, etc. The pretreatment step 704 involves exposing the surface of the substrate 720 to the microwave-generated argon-hydrogen plasma environment for at least one minute, wherein the microwave-generated argon-hydrogen plasma is generated at a power range between 50 W and 1000 W for a period of time between 10 seconds and 300 seconds, with a desired operation including a power of 600 W for 60 seconds.

The surface coating step 706 includes applying, via a microwave plasma chemical vapor deposition process, a surface coating 722 onto the surface of the substrate 720. Applying the surface coating 722 onto the surface of the substrate 720 includes feeding a precursor 711 containing a silicon-oxide material with a carrier gas onto the surface of the substrate 720 employing the microwave plasma chemical vapor deposition process. In one embodiment, the precursor containing the silicon-oxide material with the carrier gas includes hexamethyldisiloxane (HMDSO) as the precursor and oxygen (O₂) as the carrier gas. In one embodiment, the precursor 711 containing the silicon-oxide material with the carrier gas includes triethoxy silane as the precursor and oxygen (O₂) as the carrier gas. The precursor containing the silicon-oxide material may combined with the carrier gas at a desired ratio of the precursor to the carrier gas within a range between 2% and 30%, with a desired ratio of 10% in one embodiment. The microwave plasma chemical vapor deposition process includes operating at a microwave power of 100 W at a frequency of 2.45 GHz at a temperature range between 30 C and 100 C, with the temperature being 45 C in one embodiment. Operating at a microwave power frequency of 2.45 GHz at a temperature of 45 C permits coating of substrates fabricated from one of a variety of materials with minimal risk of thermal damage or distortion. The bulk of the SiOx surface coating 722 is a SiO+SiO2 mixture, wherein SiO moieties form bonds and the SiO2 enhances wettability and hydrophilic behavior of the surface coating 722.

A silane coupling agent 723 can be used after depositing the SiOx surface coating 722 to further enhance bonding to the polymer that is yet to be applied. The R term shown on the drawings may be one of a variety of functional groups, such as an amine, acrylate, vinyl, olefin, epoxy, or others. The R is chosen to be reactive with the specific polymer of the polymeric film material, e.g., the polymeric fill material 216 that is shown with reference to FIG. 4.

The post-treatment step 708 includes exposing the surface coating 722 to a gas composed of at least one of oxygen and nitrogen gases. The coupling step 710 includes executing a silane-coupling process to the surface coating 722. The gas can be either O2 or N2, and is dependent upon the polar groups to make a strong chemical bond with epoxy. The gas may instead be a reactive mixture. In one embodiment, the coupling step 710 is optional.

Although the process 700 is described with reference to applying the surface coating to a surface of a substrate that is composed of electrical steel, it is appreciated that the process can be employed on other metal-based substrates. Examples of other metal-based substrates include stainless steel, aluminum, electrical steel, low carbon steel, and magnesium, etc.

Although the process 700 is described with reference to applying the surface coating to a surface a substrate that is composed of electrical steel, it is appreciated that the process can be employed on a plastic-based substrate, examples of which include polyurethane, polycarbonate, polyethylene, and polytetrafluoroethylene (PTFE). Other examples include epoxy, phenolic, polyamide, polyimide, polybutylene terephthalate, benzoxazine, bismaleimide, and cyanate ester.

Furthermore, the surface coating may be applied onto planar and spatially-varied geometries employing a nanosecond pulsing operation of the microwave power.

FIG. 8 illustrates a reaction mechanism associated with bonding a fill material 802 onto a surface 812 of a substrate 810 in a manner described hereinabove. The surface 812 of the substrate 810 includes an embodiment of the SiOx surface coating 814. A silane coupling agent 816 can be used after depositing the SiOx surface coating 814 to further enhance bonding to the fill material 802. The R term may be one of a plurality of functional groups, such as an amine, acrylate, vinyl, olefin, epoxy, or others. The R term is selected to be reactive with the fill material 802, as shown. The resultant bond formed by the reacted silane coupling agent 816′ between the SiOx surface coating 814 and the fill material 802 is illustrated.

Overall, the concepts described herein facilitate a significant improvement in flow distribution of epoxies or other resins that are employed as polymeric fill materials, and enhances adhesion by hydroxyl group chemical bonding. Furthermore, the concepts provide a dry-chemistry process that avoids or eliminates issues with ionic contamination or moisture contamination that is associated with wet chemistry processes. Furthermore, the coatings may be tailored to have other polar groups, e.g., nitrogen, sulfur, chloride etc., for strong chemical bonds via the plasma treatment process, or an additional wet-chemistry application of second silane layer. The concepts provide increased chemical resistance of bond, particularly to H₂O, oils, and glycols, and increased resistance to thermal stresses and thermal shock.

The concepts described herein are applicable to epoxy, polyurethane, phenolic, or thermoplastics substrates used for encapsulating printed circuit boards, transistors, capacitors, or other components.

The concepts described herein are applicable to replace a stator slot liner that is used to provide electrical insulation between the stator windings 212 and the stator slots 210 that are shown with reference to FIG. 2 to prevent damage during winding insertion. In one embodiment, the coating may be applied by dip-coating after the SiOx layer has been deposited.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

What is claimed is:

1. A method for bonding a polymeric fill material onto a surface of a substrate, the method comprising:
exposing the surface of the substrate to a microwave-generated argon-hydrogen plasma for a predetermined time period;
applying, via a microwave plasma chemical vapor deposition process, a silicon-oxide (SiOx) surface coating onto the surface of the substrate;
executing a post-treatment process to the SiOx surface coating;
applying the polymeric fill material onto the substrate; and
curing the polymeric fill material.

2. The method of claim 1, wherein exposing the surface of the substrate to the microwave-generated argon-hydrogen plasma for a predetermined time period comprises exposing the surface of the substrate to the microwave-generated argon-hydrogen plasma at 600 W of power for at least sixty seconds.

3. The method of claim 1, wherein applying, via the microwave plasma chemical vapor deposition process, the SiOx surface coating onto the surface of the substrate comprises feeding a precursor containing a silicon-oxide material with a carrier gas onto the surface of the substrate employing the microwave plasma chemical vapor deposition process.

4. The method of claim 3, wherein the precursor containing the silicon-oxide material with the carrier gas comprises hexamethyldisiloxane (HMDSO) as the precursor and oxygen (O₂) as the carrier gas.

5. The method of claim 3, wherein the precursor containing the silicon-oxide material with the carrier gas comprises triethoxy silane as the precursor and oxygen (O₂) as the carrier gas.

6. The method of claim 3, further comprising feeding the precursor containing the silicon-oxide material with the carrier gas at a ratio of 10% of the precursor to the carrier gas.

7. The method of claim 3, wherein applying the SiOx surface coating onto the surface of the substrate employing the microwave plasma chemical vapor deposition process comprises operating at a microwave power of 100 W at a frequency of 2.45 GHz at a temperature range between 30 C and 100 C.

8. The method of claim 1, wherein executing the post-treatment process to the SiOx surface coating comprises exposing the SiOx surface coating to a gas composed of at least one selected from the group of oxygen and nitrogen gases.

9. The method of claim 1, wherein the surface of the substrate is fabricated from electrical steel.

10. The method of claim 1, wherein the surface of the substrate is fabricated from a metal-based substrate.

11. The method of claim 10, wherein the metal-based substrate comprises a substrate fabricated from stainless steel, aluminum, electrical steel, low carbon steel, or magnesium.

12. The method of claim 1, wherein the surface of the substrate is fabricated from a plastic-based substrate.

13. The method of claim 12, wherein the plastic-based substrate comprises a substrate fabricated from a polyurethane, a polycarbonate, a polyethylene, or a polytetrafluoroethylene (PTFE).

14. The method of claim 1, wherein the polymeric fill material adheres to the surface of the substrate via the SiOx surface coating subsequent to the curing.

15. The method of claim 1, further comprising:
inserting a permanent magnet into the substrate, and then:
exposing the surface of the substrate and a surface of the permanent magnet to the microwave-generated argon-hydrogen plasma for the predetermined time period; and
applying, via the microwave-generated plasma chemical vapor deposition process, the SiOx surface coating onto the surface of the substrate and the surface of the permanent magnet.

16. The method of claim 15, wherein the polymeric fill material adheres to the surface of the substrate and the permanent magnet via the SiOx surface coating subsequent to the curing.

17. A method for bonding a polymeric fill material onto a surface of a substrate, the method comprising:
exposing the surface of the substrate to a microwave-generated argon-hydrogen plasma for a predetermined time period;
applying, via a microwave plasma chemical vapor deposition process, an adhesive-enhancing surface coating onto the surface of the substrate;
executing a post-treatment process to the adhesive-enhancing surface coating;
executing a silane-coupling process to the adhesive-enhancing surface coating; and
applying the polymeric fill material onto the substrate.

18. The method of claim 17, wherein applying, via the microwave plasma chemical vapor deposition process, the adhesive-enhancing surface coating onto the surface of the substrate comprises feeding a precursor containing a silicon-oxide material with a carrier gas onto the surface of the substrate employing the microwave plasma chemical vapor deposition process.

19. A method for preparing a surface of a substrate, the method comprising:
exposing the surface of the substrate to a microwave-generated argon-hydrogen plasma for a predetermined time period;
applying, via a microwave plasma chemical vapor deposition process, a silicon-oxide (SiOx) surface coating onto the surface of the substrate; and
executing a post-treatment process to the SiOx surface coating.

20. The method of claim 19, wherein applying, via the microwave plasma chemical vapor deposition process, the SiOx surface coating onto the surface of the substrate comprises feeding a precursor containing a silicon-oxide material with a carrier gas onto the surface of the substrate employing the microwave plasma chemical vapor deposition process.
